(19) United States
(12) Patent Application Publication
(10) Pub. No.: US 2026/0293035 A1
(43) Pub. Date: Sep. 24, 2026

(54) ROW RACK POWER DISTRIBUTION

(71) Applicant: Cisco Technology, Inc., San Jose, CA (US)

(72) Inventors: Joel Richard Goergen, Soulsbyville, CA (US); Elizabeth Kochuparambil, Morgan Hill, CA (US); Kameron Rose Hurst, Sonora, CA (US)

(21) Appl. No.: 19/233,376

(22) Filed: Jun. 10, 2025

Related U.S. Application Data
(60) Provisional application No. 63/775,588, filed on Mar. 21, 2025.

(51) Int. Cl. H05K 7/14; H05K 7/18; H05K 7/20

(52) U.S. Cl. CPC H05K 7/1492; H05K 7/18; H05K 7/20172; H05K 7/20209

(57) ABSTRACT

An apparatus that includes at least one rack having a front side, a back side, a left side and a right side, and plurality of rows each defining a shelf to house power consuming devices. The apparatus further includes at least one column of a plurality of power supply units mounted externally to the front side, the back side, the left side or the right side of the at least one rack. The at least one column of the plurality of power supply units extends along a height of the at least one rack. One or more connection components connect power output from the plurality of power supply units into individual rows of the plurality of rows of the at least one rack to supply power to power consuming devices housed in rows of the at least one rack.

### CROSS REFERENCE TO RELATED APPLICATION

This application claims priority to U.S. Provisional Patent Application No. 63/775,588, filed Mar. 21, 2025, the entirety of which is incorporated herein by reference.

### TECHNICAL FIELD

The present disclosure relates to rack power distribution.

### BACKGROUND

Current rack power distribution systems involve crude arrangements for distributing power inside the rack. Traditional rack power shelf systems distribute power from the top through the rack, or from the bottom through the rack. In particular, these systems inefficiently use rack space and create inefficiency in high amperage loss involved in getting power to cards in the middle or end of the power distribution system in the rack.

Outside of building wiring, rack power density is also limited by physical space. Today's rack power limitation is approximately 18 kilowatts (kW) per rack unit (RU), available from the front or rear. To enable higher power usage (e.g., 300 kW) in a rack, 17 RU of the 44 RU or 48 RU rack striations would be needed for power input, taking space from artificial intelligence (AI) engineers or switching/routing functionality.

### BRIEF DESCRIPTION OF THE DRAWINGS

FIG. 1A illustrates an example of a rack for which the techniques for externally mounting/attaching power supply units and delivering power in-row are employed, according to an example embodiment.

FIG. 1B illustrates one or more columns of power supply units mounted externally to the front side, the back side, the left side or the right side of a rack, according to an example embodiment.

FIG. 2 illustrates a single column of power supply units, according to an example embodiment.

FIG. 3A illustrates a column of power supply units that is suitable for externally mounting to the front side of a rack, according to an example embodiment.

FIG. 3B illustrates a column of power supply units that is suitable for externally mounting to the back side (rear) of a rack, according to an example embodiment.

FIG. 3C illustrates a pair of two adjacent (dual) columns of power supply units that are suitable for externally mounting to the left side or the right side of a rack, according to an example embodiment.

FIG. 4A illustrates a rack having pairs of columns of power supply units mounted to the left side and to the right side of the rack, according to an example embodiment.

FIG. 4B illustrates a bus bar arrangement for delivering power from an externally mounted column of power supply units on a rack to power consuming devices within the rack, according to an example embodiment.

FIG. 5 illustrates a double rack configuration in which two racks are arranged side-by-side to each other and two pairs of double-stacked columns of power supply units are externally mounted to the sides of the two racks, according to an example embodiment.

FIG. 6A shows two adjacent columns of power supply units arranged to enable air or liquid flow across one column to the other column, according to an example embodiment.

FIG. 6B illustrates a top view of a column of power supply units depicted in FIG. 6A, and showing a space allocated for power supply units, spaces for cables, and a space for a plenum or side plates to carry air or liquid for cooling columns of power supply units, according to an example embodiment.

FIG. 7 illustrates positioning of fans in columns of power supply units, according to an example embodiment.

FIG. 8 illustrates an alternative arrangement of power supply units in a column in which the power supply units are oriented horizontally and stacked on each other, according to an example embodiment.

FIG. 9 is a flow chart depicting a method for providing power into a rack, according to an example embodiment.

FIG. 10 illustrates a block diagram of a rack system for an example large core router that employs columns of power supply units, according to an example embodiment.

FIG. 11A-11F illustrate techniques associated with a current share bus, also called “I Share” and cold redundancy techniques that may be used in connection with the in-row distribution of power techniques depicted in FIGS. 1A, 1B, and 2, 3, 4A, 4B, 5, 6A, 6B and 7-9, according to an example embodiment.

### DESCRIPTION OF EXAMPLE EMBODIMENTS

### Overview

Presented herein are techniques for positioning power supply units (PSUs) on the sides (or front and rear) of a rack, rather than internally on one or more shelves of a rack. Rack spacing is used as a means to deliver power in-row while avoiding taking up internal rack space. This allows for more networking and artificial intelligence (AI) processing cards, etc., to fit into a 44 RU to 48 RU rack, for example. Moreover, distribution of power within a rack can be achieved with much greater efficiency than prior techniques that distribute power from the top or from the bottom.

In one form, an apparatus is provided that includes at least one rack having a front side, a back side, a left side and a right side, and a plurality of rows each defining a shelf to house power consuming devices. The apparatus further includes at least one column of a plurality of power supply units mounted externally to the front side, the back side, the left side or the right side of the at least one rack. The at least one column of the plurality of power supply units extends along a height of the at least one rack. One or more connection components connect power output from the plurality of power supply units into individual rows of the plurality of rows of the at least one rack to supply power to power consuming devices housed in rows of the at least one rack.

### Example Embodiments

Arrangements are presented herein to enable distribution of substantial power to a rack, such as 300 kilowatts (kW) to 400 kW or more per rack. These arrangements involve positioning the power shelves each comprising a plurality of power supply units (PSUs) externally on the side of the rack, and using the rack spacing as a means to distribute power in-row while avoiding taking up rack space. This allows for more networking and artificial intelligence (AI) and other processing cards, etc., to fit into a 44 RU to 48 RU, for example, rack.

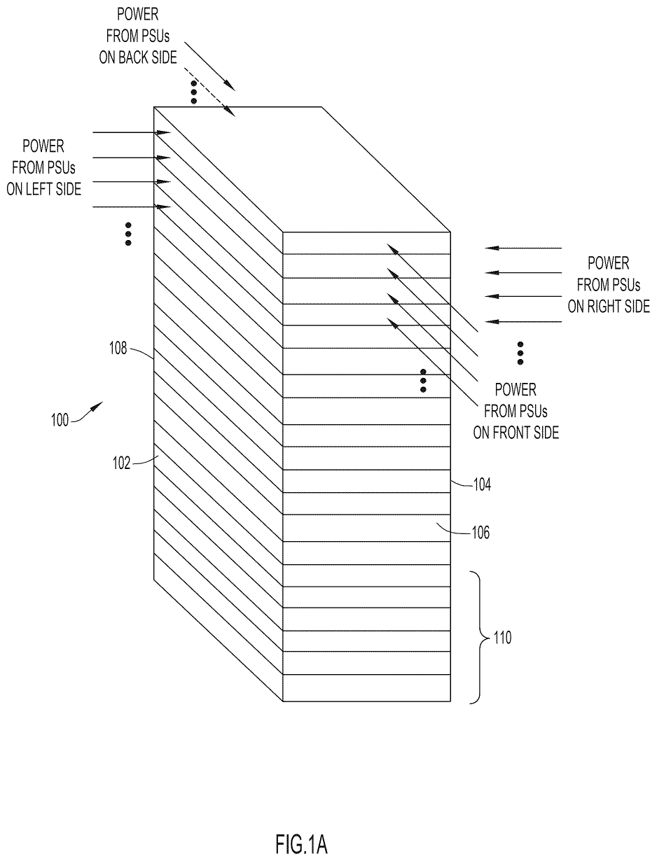

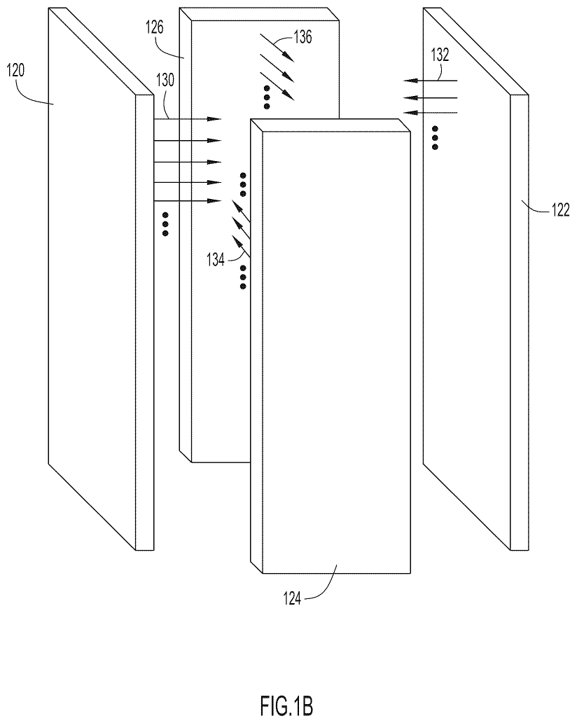

FIG. 1A shows an example of a rack 100 to which power supply units are externally mounted/attached, according to an example embodiment. The rack 100 can have any range of dimensions. For example, the rack 100 can be 19 inches wide or 23 inches wide, and may follow industry standards for dimensions. The rack 100 includes a left side 102, a right side 104, a front side 106 and a back (rear) side 108. In one example, the rack has a rectangular profile in which the left side 102 and right side 104 are deeper than the width of the front side 106 and back side 108. The rack 100 further includes a plurality of rows 110 and each row defines or includes a shelf to house one or more power consuming devices, such as networking equipment, computing equipment, storage equipment, etc. These power consuming devices may reside on trays that slide into and out of a given row (shelf) in the rack. For example, there may be one or more compute trays on which computing equipment may reside that include central processing units (CPUs), graphic processing units (GPUs), one or more networking trays on which networking equipment may reside (switches, routers, etc.), one or more memory trays on which memory devices may reside, etc.

PSUs are traditionally positioned within the physical space of the rack, taking up space on the shelves of the rows 110. Techniques are presented herein to move the PSUs out of the rack and to the sides and/or front and rear of the rack. In this regard, as shown in FIG. 1A, the PSUs are positioned external to the rack 100 and power is delivered, at the row-level (shelves), into the rack, from one or more of the left side 102, the right side 104, the front side 106 and the back (rear) side 108.

Reference is now made to FIG. 1B. FIG. 1B complements FIG. 1A and shows options for one or more columns of a plurality of PSUs to be mounted externally to the front side, the back side, the left side and/or the right side of a rack. For simplicity in illustration, the rack itself is not shown in FIG. 1B. Specifically, FIG. 1B shows a column 120 of PSUs (PSU column) for the left side, a column 122 of PSUs for the right side, a column 124 of PSUs for the front side and a column 126 of PSUs for the back side. The columns 120, 122, 124 and 126 extend along a height dimension of a rack. The arrows 130 from column 120 of PSUs are to indicate that power is delivered at the various rows/levels of the rack externally from the left side of the rack. The arrows 132 from column 122 of PSUs indicate that power is delivered at the various rows/levels of the rack externally from the right side of the rack. The arrows 134 from column 124 of PSUs indicate that power is delivered at the various rows/levels of the rack externally from the front side of the rack. Finally, the arrows 136 of column 126 of PSUs indicate that power is delivered at the various rows/levels of the rack externally from the back side (rear) of the rack. In some implementations, there may be only one column of PSUs mounted externally to the left side, right side, front side or back side; and in other implementations, there may be a column of PSUs mounted on two, three or all four sides of the rack.

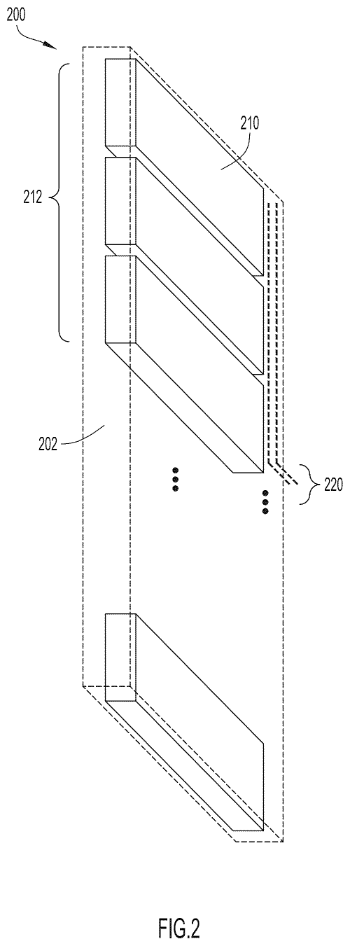

Reference is now made to FIG. 2. FIG. 2 shows a PSU column 200 that includes a housing 202 to contain a plurality of PSUs 210. Each PSU 210 may have a predetermined power capacity, such as 6300 Watt (W) capability (made of dual 3150 W PSUs), with 13 amps per feed. The dimensions of a single PSU 210 may be approximately 1.7 inches high by 5.25 inches wide by 19 inches deep. Traditionally, the PSUs 210 are arranged on a shelf of the rack (FIG. 1A) in a horizontal orientation (wide side down) in a row (90 degrees to the arrangement shown in FIG. 2.) However, arranging and stacking the PSUs with the vertical orientation shown in FIG. 2 produces a smaller profile which may be desirable on the outside of a rack to take up less space around the exterior of the rack. Said another way, each of the plurality of PSUs 210 may be arranged in a vertical orientation and vertically stacked on top of each other in the vertical orientation.

The column 200 may include a housing 202 that has a depth of 21 inches and a width of 1.75 inches, and which contains the plurality of PSUs 210. The column 200 of PSUs can create an in-row power distribution arrangement for bus bars and cables to deliver power in from the sides of a rack. A linear arrangement or segment of three PSUs 210 occupies a space that typically is used for a power shelf 212 in a rack, when arranged in a horizontal orientation. In other words, in one example, the PSU column may be formed by stacking power shelves, each power shelf comprising a predetermined number of PSUs 210, e.g., three PSUs 210 included in power shelf 212, as shown in FIG. 2, which is common for a 3-phase power system. If the power shelf is connected to fault managed power (with integrated fault detection capabilities) or High Voltage Direct Current (HVDC) power, then there could be any number of PSUs in a given shelf/segment of PSUs in PSU column 200. The advantage of using PSUs in preconfigured power shelves is that each power shelf (consisting of multiple PSUs) can be an individually removable component.

The PSU column 200 may include cables 220 (power send and power return) for segments of PSUs (e.g., a segment of 3 PSUs—a power shelf), as shown in FIG. 2. The cables 220 may take the form of insulated conductors/wires.

Bringing power in from the sides as shown in FIGS. 1A and 1B, as opposed to from the top and bottom, allows for the power to be delivered to the equipment in the rack more directly, significantly reducing loss associated with power distribution cabling, etc. An example of loss associated with existing techniques (from the top and/or from the bottom) is that a 2000 W line card at a bottom slot of a rack, where the power comes from the top, loses over 100 watts just delivering the power to the slot at the bottom of the rack.

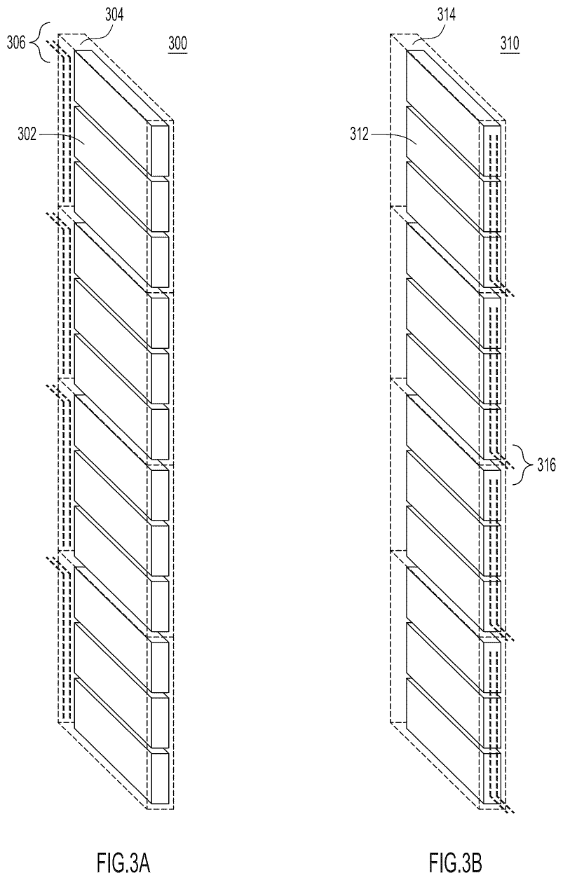

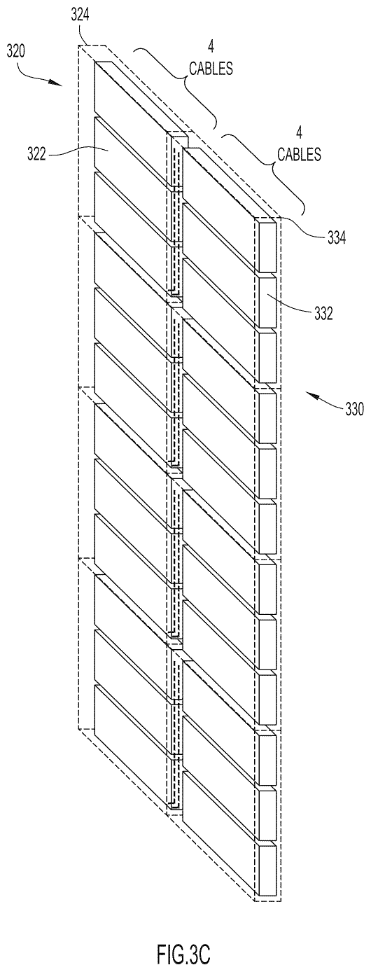

Turning now to FIG. 3A-3C, example arrangements of PSU columns to enable in-row power distribution are described. FIG. 3A shows a PSU column 300 of PSUs 302 that is suitable for externally mounting to the front side of a rack. The PSU column 300 includes a housing 304 in which the PSUs 302 are arranged and contained. Cables 306 (send and return) are provided for segments of (e.g., three) PSUs 302, such as for each power shelf consisting of multiple PSUs as described above in connection with FIG. 2. Similarly, FIG. 3B shows a PSU column 310 of PSUs 312 that is suitable for the back (rear) side of a rack. The PSU column 310 includes a housing 314 in which the PSUs 312 are arranged and contained. Cables 316 (send and return) are provided for segments of (e.g., three) PSUs 312, that is, for each power shelf comprising multiple PSUs.

FIG. 3C shows a pair of two adjacent (dual) PSU columns 320 and 330 that are suitable for the left side of a rack and the right side of the rack. The side-by-side parallel arrangement of the PSU columns 320 and 330 is suitable for the left and right sides of a rack since the left and right sides of a typical rack are deeper (corresponding to a depth of the rack) than a width of the front and rear sides. PSU column 320 includes PSUs 322 contained in a housing 324 and PSU column 330 includes PSUs 332 contained in a housing 334. FIG. 3C shows that there may be 4 power cables (cords) for PSU column 320 and PSU column 330 to provide raw input power to the PSUs in these columns, as described further below. An advantage to the side-by-side arrangement of the PSU columns 320 and 300 is that they have a narrower profile along the left and right sides when mounted to a rack.

The PSU columns shown in FIG. 3A-3C may be suitable for a 42 RU rack (73.5 inches heigh) or a 48 RU rack (84 inches heigh). Again, positioning columns of PSUs externally on the rack allows for distributing power laterally or in-row from the PSUs into the rack.

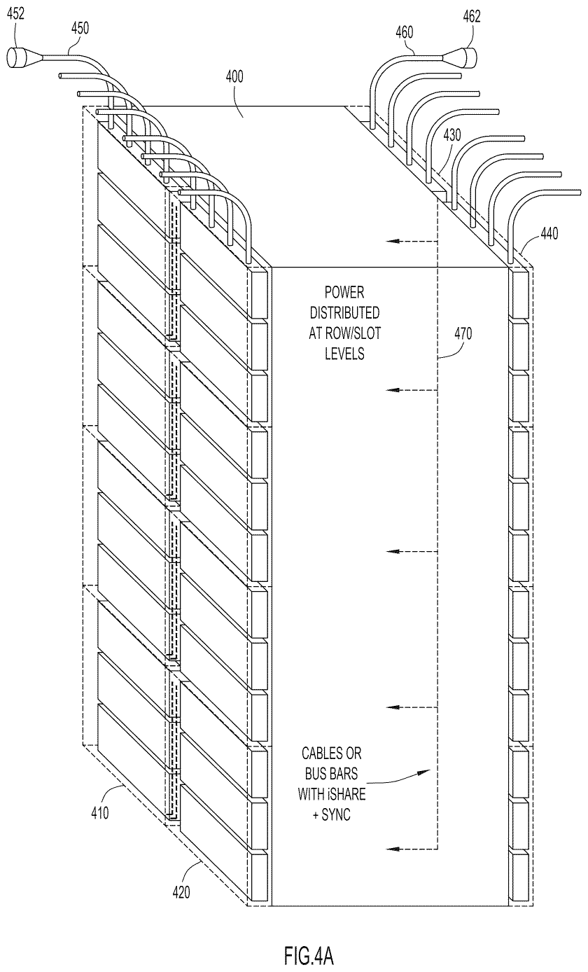

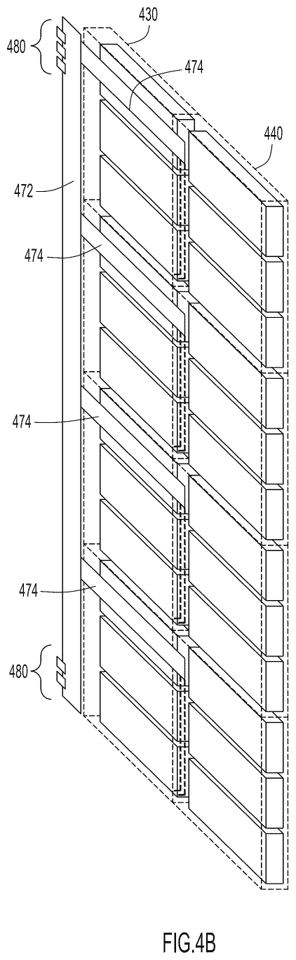

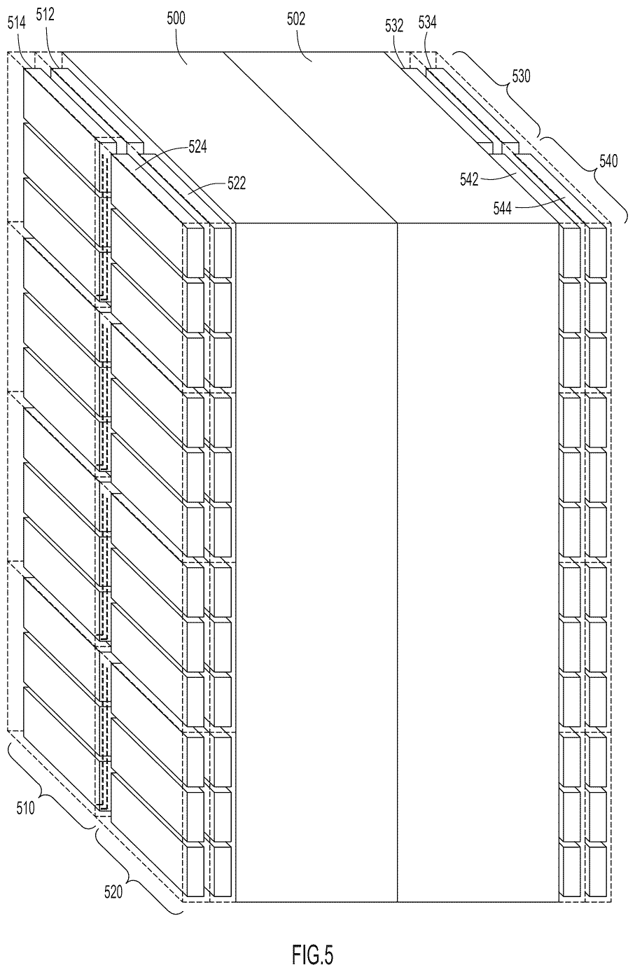

Referring now to FIG. 4A, one example of a rack 400 having externally mounted PSU columns is shown. In this example, the side-by-side adjacent PSU column arrangement of FIG. 3C is employed for the rack 400. That is, side-by-side/adjacent PSU columns 410 and 420 are provided on the left side of the rack 400 and side-by-side PSU columns 430 and 440 are provided on the right side of the rack 400. In this example, the rack 400 may be a 19 inch wide, 42 RU rack. There are 8 power cords 450, each with a connector 452, for PSU columns 410 and 420 (4 cords for each column) and similarly 8 power chords 460, each with a connector 462, for PSU columns 430 and 440. In one example, each of the power cords may provide 50 amp, 3-phase power to each PSU column. Other types of raw input power may be provided to the PSU columns. It is also understood that receptacles could be used instead of power cords.

Power is distributed from PSUs in the PSU columns 410, 420, 430 and 440 internally into the rack at the various rows (slot or shelf levels), by one or more connection components 470. For example, one or more connection components may be cables or bus bars to distribute power at each slot/row (shelf) level within the rack from the PSU columns 410 and 420 attached to the exterior on the left side of the rack 400, and from the PSU columns 430 and 440 attached to the exterior on the right side of the rack 400. Power distribution loss associated with the power distribution arrangement shown in FIG. 4A into rack 400 can be significantly reduced, such as by nearly 90%. Moreover, power can be managed using current share (i-Share) and synchronization (sync) techniques described below.

FIG. 4B shows one example of distributing power from an externally mounted PSU column into a rack. Specifically, FIG. 4B shows a side-by-side adjacent PSU column arrangement that includes PSU columns 430 and 440 from FIG. 4A, as an example. A bus bar arrangement is provided that includes a vertical bus bar 472 and horizontal bus bars 474 that extend across PSUs at different positions in the PSU column and connect to the cables for each segment (power shelf) of PSUs. There are positive (+) and negative (−) conductor paths (not shown) within the vertical bus bar 472 and horizontal bus bars 474. The horizontal bus bars 474 connect to the vertical bus bar 472. In addition, there are card power connectors 480 positioned along vertical bus bar 472 that are configured to connect to power consuming devices at various rows in the rack. FIG. 4B shows two positions for the card power connectors 480 but that is only a simplified illustration and it should be understood that numerous more card power connectors are provided along the length of the vertical bus bar 472. Thus, horizontal bus bars 474 connect to the PSUs (or segments (power shelves) of PSUs) in the PSU column and to the vertical bus bar 472, and the card power connectors 480 on the vertical bus bar 472 connect power to the power consuming devices at the various rows inside the rack. FIG. 4B shows the bus bars for PSU column 430 but it is to be understood that a similar arrangement of bus bars may be used for PSU column 440, or the horizontal bus bars 474 may extend far enough to electrically connect to the PSUs in PSU column 440.

Reference is now made to FIG. 5. FIG. 5 shows a double rack configuration comprising a first rack 500 and a second rack 502 arranged (side-by-side) to each other such that a right side of the first rack 500 abuts a left side of the second rack 502. Each of the first and second racks 500 and 502 have a plurality of rows, each row defining a shelf to house power consuming devices. A first pair of columns of PSUs arranged adjacent and parallel to each other is mounted external to a left side of the first rack 500, and a second pair of columns of PSUs arranged adjacent and parallel to each other is mounted external to a right side of the second rack 502. More specifically, mounted to the left side of rack 500 are two double-stacked PSU columns 510 and 520. That is, PSU column 510 and PSU column 520 each comprises two layers of PSUs. PSU Column 510 includes a first column layer 512 of PSUs and a second column layer 514 of PSUs attached onto the first column layer 512 of PSUs. Similarly, PSU column 520 includes a first column layer 522 of PSUs and a second column layer 524 of PSUs attached onto the first column layer 522 of PSUs.

In a similar manner, mounted to the right side of rack 500 are two double-stacked PSU columns 530 and 540. PSU column 530 includes a first column layer 532 of PSUs and a second column layer 534 of PSUs attached onto the first column layer 532 of PSUs. Similarly, PSU column 540 includes a first column layer 542 of PSUs and a second column layer 544 of PSUs attached onto the first column layer 542 of PSUs.

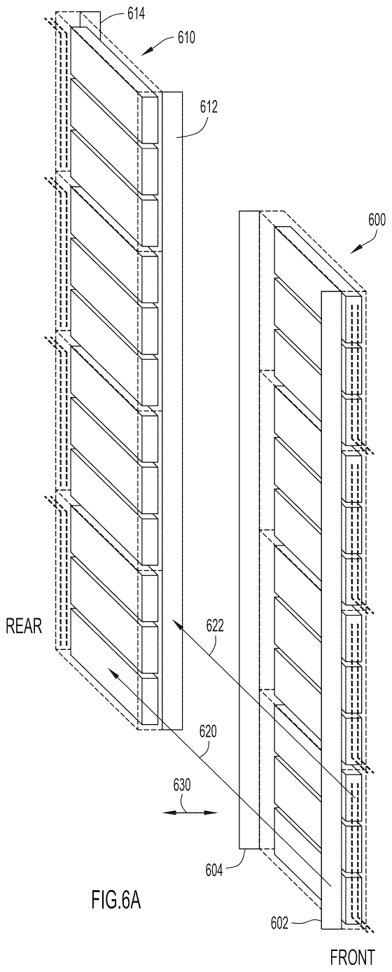

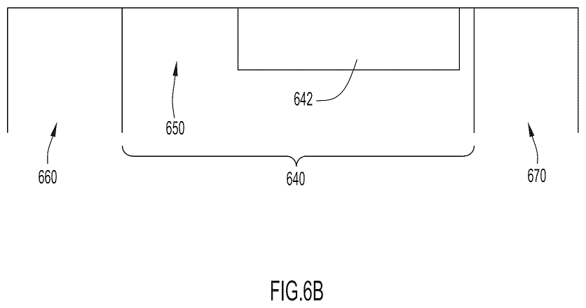

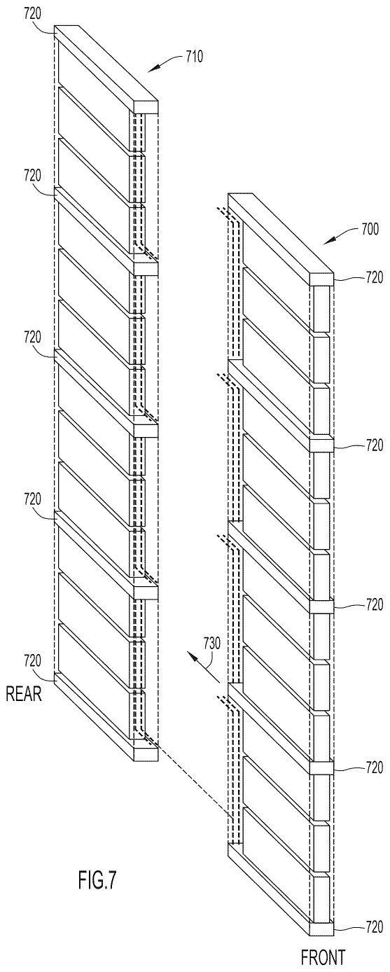

The columns of PSUs may be equipped for air or liquid cooling. To this end, reference is now made to FIG. 6A. FIG. 6A shows adjacent PSU columns 600 and 610 to be attached to the left side of a rack (not shown in FIG. 6A), where the PSU column 600 is towards the front of the rack and the PSU column 610 is towards the back (rear) of the rack. There is an exaggerated gap between the PSU columns 600 and 610 in FIG. 6A solely to illustrate the flow or coolant (air or liquid) from front to rear, that is, from the PSU column 600 to the PSU column 610. Each of the PSU columns 600 and 610 includes a plenum space to enable flow for cooling of the PSU columns. Specifically, there are air plenums 602 and 604 that extend on respective sides along the length of PSU column 600. Similarly, there are air plenums 612 and 614 that extend on respective sides along the length of PSU column 610. If liquid cooling is used instead of air cooling, side plates are used instead of air plenums.

Air enters air plenum 602 and is directed from the front across the PSUs in PSU column 600 to air plenum 604, and then is directed to air plenum 612 across the PSUs in PSU column 610 to air plenum 614. The direction of air flow is shown by arrows 620 and 622 in FIG. 6A. To facilitate this, there may be a slight offset in the lateral alignment of PSU column 600 and PSU column 610, as shown at reference numeral 630, to ensure that air from plenum 604 continues to plenum 612.

FIG. 6B shows a view from the top of one of the PSU columns 600 or 610 the front column of PSUs looking down the column. There is a PSU space 640 for PSUs 642, a plenum space 650 for air flow next to the PSUs 642, and cable spaces 660 and 670 adjacent to the plenum space 650 and the PSU space 640 for cables. The PSU 642 may extend only slightly into the PSU space 640.

FIG. 7 illustrates how fans can be positioned with respect to PSU columns 700 and 710 arranged to be mounted to a side of a rack, similar to the arrangement shown in FIG. 6A. Fan modules 720 may be positioned in fan trays at multiple locations along PSU column 700 and 710. In the example of FIG. 7, there are three fan modules 720 for each column. Air flow from the fan modules 720 from front to back (rear) as shown by arrow 730 based on an assumption that the front is in the cold isle or exposed to cooler air, and the rear (back) is in the hot aisle or exposed to hotter air than the front. The fan modules 720 for the PSU column 700 may be field-replaceable units in fan trays from the front side, whereas the fan modules for the PSU column 710 may be in fan trays that are replaceable from the back side. Each fan module 720 may include at least one fan and a controller card that automatically adjusts air flow based on thermal conditions in the surrounding air.

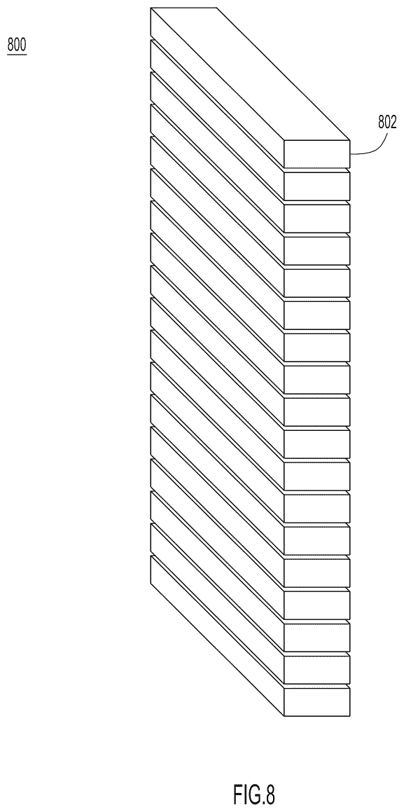

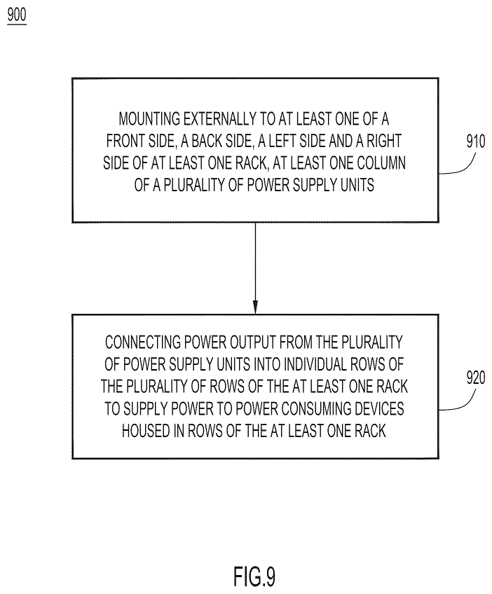

Reference is now made to FIG. 8 for a description of an alternative arrangement of a PSU column. Rather than having the PSUs turned on their side in the vertically stacked arrangement (to have a narrower lateral profile) as shown in FIGS. 2, 3A, 3B, 3C, 4A, 4B, 5, 6A, 6B and 7, the PSUs can be oriented horizontally (with the wider side horizontal) resulting in a wider lateral profile as shown in FIG. 8. This may be acceptable for situations where space on the sides of a rack is not limited or when it is otherwise not necessary to minimize the space on the sides of a rack that is occupied by a column of PSUs. Thus, FIG. 8 shows a PSU column 800 comprising a plurality of PSUs 802 each of which is arranged in a horizontal orientation and vertically stacked on top of each other in the horizontal orientation. The PSU column 800 can be used in any of the arrangements shown in FIGS. 2, 3A, 3B, 3C, 4A, 4B, 5, 6A, 6B and 7.

FIG. 9 illustrates a flow chart depicting a method 900 according to an example embodiment. The method 900 involves, at step 910, mounting externally to at least one of a front side, a back side, a left side and a right side of at least one rack, at least one column of a plurality of power supply units. The at least one column of the plurality of power supply units extends along a height of the at least one rack. Step 910 of mounting may involve mounting at least two columns of power supply units arranged adjacent and parallel to each other to the front side, the back side, the left side or the right side of the at least one rack.

At step 920, the method 900 involves connecting power output from the plurality of power supply units into individual rows of the plurality of rows of the at least one rack to supply power to power consuming devices housed in rows of the at least one rack. As described above, each of the plurality of power supply units are arranged in a vertical orientation and vertically stacked on top of each other in the vertical orientation. In another form, each of the plurality of power supply units are arranged in a horizontal orientation and vertically stacked on top of each other in the horizontal orientation.

Using the techniques presented above, it is possible to deliver more than 400 kilowatts (kW) into a rack space, if more racks are combined together for a particular application, such as an artificial intelligence (AI) computing system structure. FIG. 5 shows an example of that for a two (dual) rack structure with 600 kW of power delivery.

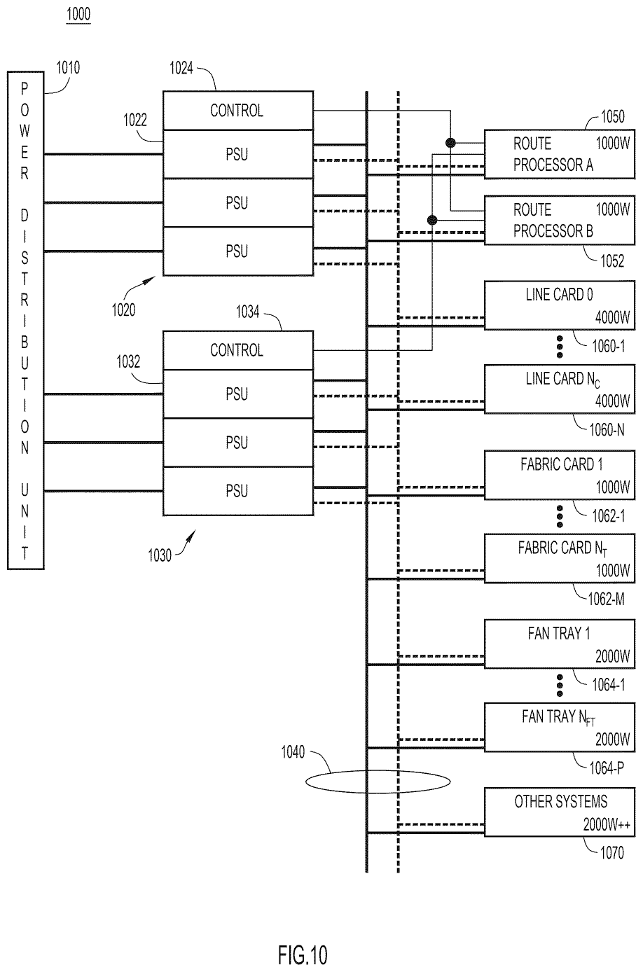

FIG. 10 illustrates a block diagram of a rack system 1000 for, as an example a large core router, for a 44 RU rack. A power distribution unit (PDU) 1010 is provided that provides input power to a first PSU column 1020 and to a second PSU column 1030. The PDU 1010 may output three-phase power, as an example, to provide Phase 1, Phase 2 and Phase 3 of power to each of the first PSU column 1020 and the second PSU column 1030. The first PSU column 1020 includes a first plurality of PSUs 1022 and the second PSU column 1030 includes a second plurality of PSUs 1032. There may be a controller (control) 1024 associated with the first PSU column 1020 and a controller 1034 associated with the second PSU column 1030. A bus bar 1040 is provided that serves as one example of a connection component that may be used to connect power output from the first plurality of PSUs 1022 and the second plurality of PSUs 1032 to power consuming devices that are also connected to the bus bar 1040. The PSU columns 1020 and 1030 are mounted externally to sides of a rack, in accordance with the example arrangements described above.

In this example, the power consuming devices include route processors 1050 and 1052, line cards 1060-1 to 1060-N, fabric cards 1062-1 to 1062-M, fan trays 1064-1 to 1064-P and other power system components 1070.

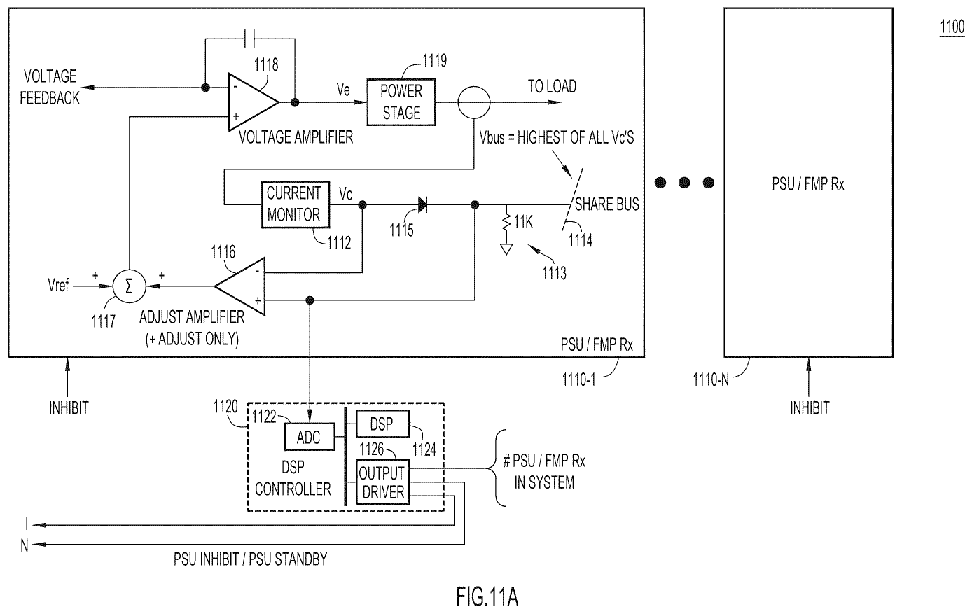

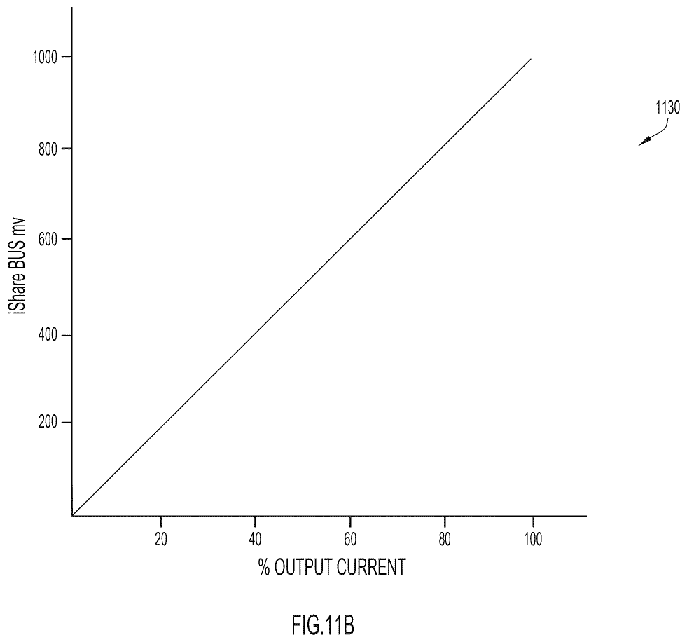

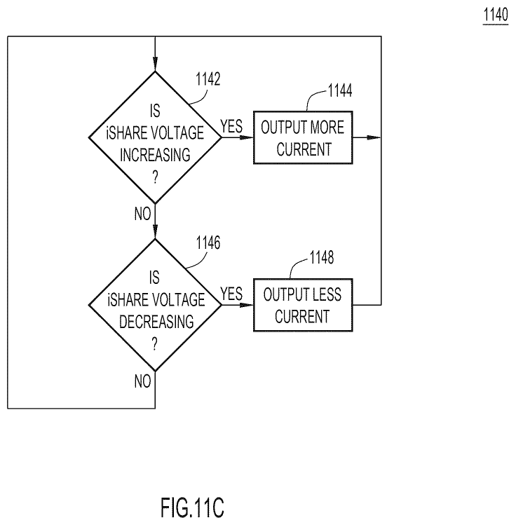

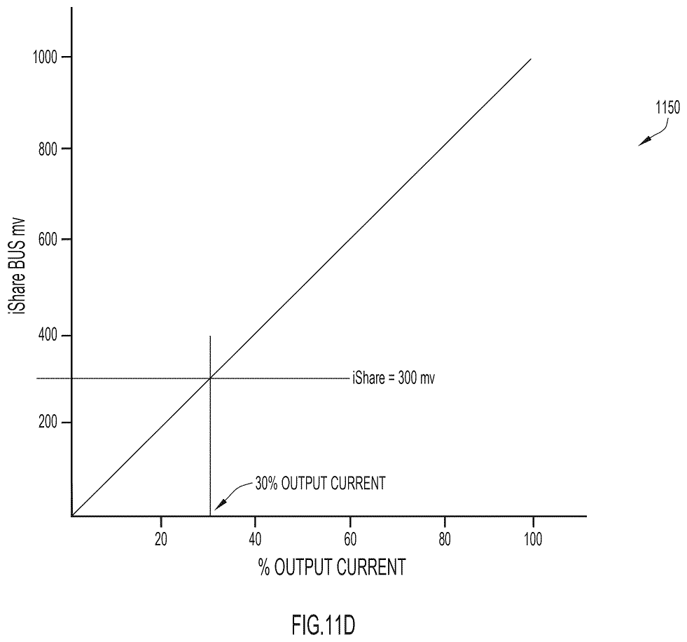

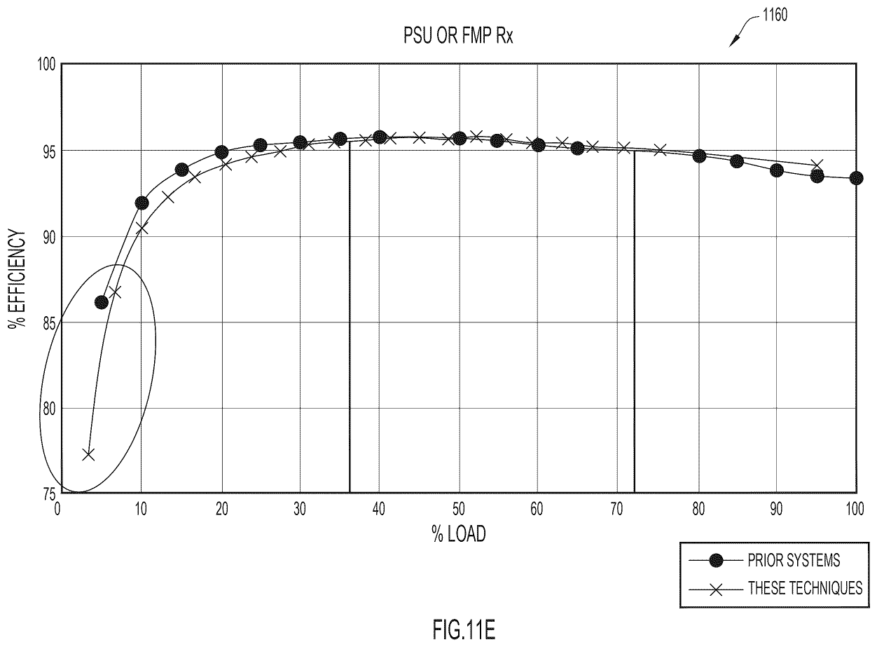

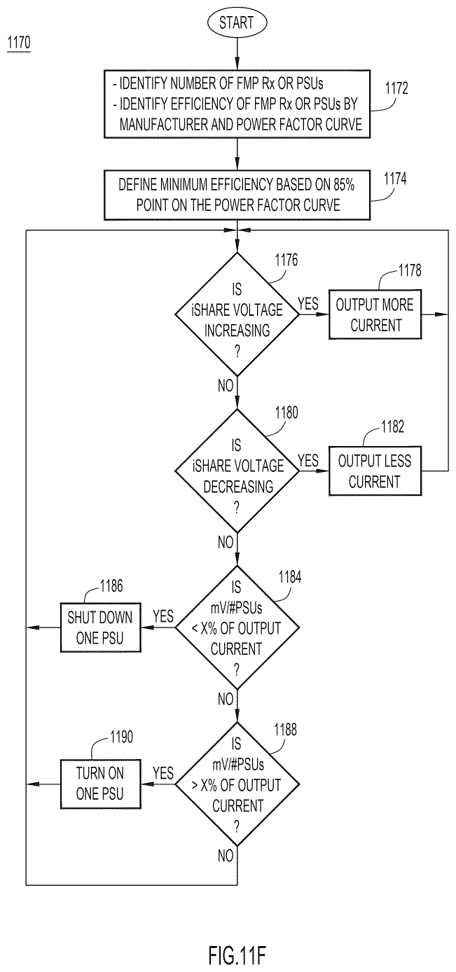

Reference is now made to FIG. 11A-11F for a description of a current share bus, also called “iShare, and cold redundancy techniques that may be used in connection with the in-row distribution of power presented herein. FIG. 11A shows a receive side of a power system 1100 that includes a plurality of PSUs 1110-1 to 1110-N and a DSP controller 1120 that may take the form of a single DSP chip or field programmable gate array (FPGA) that may reside in a power shelf with the PSUs (or FMP power receivers) 1110-1 to 1110-N. Each PSU 1110-1 to 1110-N is configured to support current share techniques and provide a current measurement onto a current share bus called “Share Bus”. The PSUs 1110-1 to 1110-N may be arranged in columns and mounted outside of a rack as described above.

Specifically, as shown for PSU 1110-1, a current monitor 1112 outputs a voltage Vc that is a measure of current provided to a load, and this current measurement is provided to the Share Bus 1114. The diode 1115 prevents current from backflowing into the PSU from the Share Bus 1114. Each PSU dumps onto the Share Bus 1114 this voltage measurement, Vc. A PSU is looking at what the highest voltage measurement is on the Share Bus and that feeds into the adjust amplifier 1116 which uses that, and the local voltage measurement Vc to output an adjustment that is then added to a reference voltage Vref by a summer 1117, which in turn is connected to the voltage amplifier 1118 to adjust the output voltage Ve into the power stage 1119 that supplies current to the load. The 11k Ohm resistor 1113 provides stability to the Share Bus 1114. It should be understood that a typical implementation will have two DSP controllers 1120, for redundancy.

The DSP controller 1120 taps onto the Share Bus 1114, via the 11k resistor 1113. The DSP controller 1120 includes an analog-to-digital converter (ADC) 1122, a DSP 1124 and an output driver 1126. The DSP controller 1120 receives a configuration input as to the number of PSUs or FMP receivers in the system, which may come from a PSU identifier (ID) pin or system software. The DSP controller 1120 thus knows which PSU is in which slot (in a rack/power shelf) and knows whether it is active or not and knows how many PSUs are in the system. There is an Inhibit control line to each PSU 1110-1 that allows the DSP controller to shut off the power output by a given PSU. In some applications, the Inhibit control line may shut down the entire power supply, including the output. Thus, the controller 1120 is in communication with the plurality of PSUs 1110-1 to 1110-N via current share bus to receive measurements made by each of the plurality of PSUs 1110-1 to 1110-N. The measurements indicate percentage of output current provided by each of the plurality of PSUs 1110-1 to 1110-N. The controller 1120 is configured to evaluate the measurements to select one or more of the plurality of PSUs 1110-1 to 1110-N to shut down in order to maintain operation of the plurality of PSUs 1110-1 to 1110-N at a desired power efficiency.

Reference is now made to FIG. 11B and FIG. 11C. The DSP controller 1120 knows the highest voltage reported on the Share Bus (iShare bus), and thus knows the percent output current from each PSU. For example, if, as shown by the curve 1130 in FIG. 11B, the DSP controller 1120 reads 400 millivolts (mV) on the Share Bus, this means that each PSU is outputting 40% of its total capacity. Thus, as shown by the DSP loop 1140 of FIG. 11C, if, at 1142, the iShare voltage is increasing, then at 1144, the PSU needs to push more current to its output. If, at 1146, the iShare voltage is decreasing, then the PSU needs to output less current at 1148, and this loop repeats until all PSUs reach an equilibrium, and the output current then settles.

With reference to FIGS. 11D and 11E, a specific example is described. There are three PSUs (or FMP receivers) in this example. If the DSP controller measures 300 mV (as the highest measured voltage reported on the Share Bus), this indicates, according to the curve 1150, that each PSU is outputting current at 30% of its load.

As shown by the percent efficiency versus percent load curve 1160 in FIG. 11E, at 30% load, no matter what is done in terms of shutting off a PSU, the system is already at near peak efficiency, so at this point, it is better to leave all three PSUs on and providing output current. However, if the DSP controller measures 50 mV, this indicates that each PSU is operating at 5% of its load. According to the curve shown in FIGS. 11E, 5% percent of the load translates to a low % efficiency (less than 80%). If the DSP controller were to shut off/inhibit 2 PSUs/FMP Rx's, this moves the % load up to approximately 15%, which increases the efficiency to close to peak efficiency (nearly 95%). Thus, by using only one PSU, a much-improved power efficiency can be achieved.

FIG. 11F illustrates a flow chart that depicts a logic flow for a control loop 1170 to control a plurality of PSUs using the principles of iShare and cold redundancy described above in connection with FIG. 11A-11E. The control loop 1170 involves, at step 1172, identifying/determining the number of fault managed power (FMP) receivers (Rx's)/PSUs in the system and also identifying/determining an efficiency of the FMP Rx's/PSUs by manufacturer efficiency or a power factor curve derived for the FMP Rx's/PSUs. At step 1174, a minimum efficiency is defined based on, for example, an 85% point on a power factor curve. At step 1176, the controller determines whether the iShare voltage is increasing. If so, then at step 1178, the PSU is controlled to output more current. At 1180, the controller determines whether the iShare voltage is decreasing. If so, then at step 1182, the PSU is controlled to output less current.

At step 1184, the controller determines whether the ratio of millivolts (mV) to the number of PSUs is less than a predetermined percentage (X%) of the output current. If so, then at 1186, the controller shuts down one PSU. Next, at step 1188, the controller determines whether the ratio of mV to the number of PSUs is greater than the predetermined percentage (X%) of the output current. If so, then the controller turns on one PSU at step 1190.

In summary, techniques are presented herein for positioning the power supply units (PSUs) on the sides (or front and rear) of a rack, and using the rack spacing as a means to deliver power in-row while avoiding taking up internal rack space. This allows for more networking and artificial intelligence (AI) processing cards, etc., to fit into a rack.

In some aspects, the techniques described herein relate to an apparatus including: at least one rack having a front side, a back side, a left side and a right side, and plurality of rows each defining a shelf to house power consuming devices; at least one column of a plurality of power supply units mounted externally to the front side, the back side, the left side or the right side of the at least one rack, the at least one column of the plurality of power supply units extending along a height of the at least one rack; and one or more connection components to connect power output from the plurality of power supply units into individual rows of the plurality of rows of the at least one rack to supply power to power consuming devices housed in rows of the at least one rack.

In some aspects, the techniques described herein relate to an apparatus, wherein each of the plurality of power supply units are arranged in a vertical orientation and vertically stacked on top of each other in the vertical orientation.

In some aspects, the techniques described herein relate to an apparatus, wherein each of the plurality of power supply units are arranged in a horizontal orientation and vertically stacked on top of each other in the horizontal orientation.

In some aspects, the techniques described herein relate to an apparatus, wherein the plurality of power supply units in the at least one column include one or more power supply unit shelves each of which includes a plurality of power supply units.

In some aspects, the techniques described herein relate to an apparatus, and including at least two columns of power supply units arranged adjacent and parallel to each other and mounted external to the front side, the back side, the left side or the right side of the at least one rack.

In some aspects, the techniques described herein relate to an apparatus, wherein the one or more connection components include cables or bus bars configured to distribute power output from the plurality of power supply units into the at least one rack at each of the plurality of rows of the at least one rack to provide power to the power consuming devices in the at least one rack.

In some aspects, the techniques described herein relate to an apparatus, wherein the at least one column includes two or more laterally stacked layers of power supply units, wherein each of the plurality of power supply units in each of the two or more laterally stacked layers of power supply units are arranged in a vertical orientation and vertically stacked on top of each other in the vertical orientation.

In some aspects, the techniques described herein relate to an apparatus, further including a housing for the at least one column of the plurality of power supply units, wherein the housing includes vertical spaces for air plenums to enable air flow across the plurality of power supply units.

In some aspects, the techniques described herein relate to an apparatus, wherein the housing further includes vertical spaces for cables.

In some aspects, the techniques described herein relate to an apparatus, further including a plurality fan modules, each fan module arranged at one of a plurality of positions in the at least one column of power supply units.

In some aspects, the techniques described herein relate to an apparatus, including first rack and a second rack positioned adjacent to each other such that a right side of the first rack abuts a left side of the second rack, each of the first rack and the second rack having a plurality of rows each defining a shelf to house power consuming devices, a first pair of columns of power supply units arranged adjacent and parallel to each other and mounted external to a left side of the first rack, and a second pair of columns of power supply units arranged adjacent and parallel to each other and mounted external to a right side of the second rack.

In some aspects, the techniques described herein relate to an apparatus, wherein each column of the first pair of columns and each column of the second pair of columns includes two or more laterally stacked layers of power supply units, wherein each of the plurality of power supply units in each of the two or more laterally stacked layers of power supply units are arranged in a vertical orientation and vertically stacked on top of each other in the vertical orientation.

In some aspects, the techniques described herein relate to an apparatus, further including a controller in communication with the plurality of power supply units via a current share bus to receive measurements made by each of the plurality of power supply units, the measurements indicating percentage of output current provided by each of the plurality of power supply units, and wherein the controller is configured to evaluate the measurements to select one or more of the plurality of power supply units to shut down in order to maintain operation of the plurality of power supply units at a desired power efficiency.

In some aspects, the techniques described herein relate to an apparatus including: at least one rack having a front side, a back side, a left side and a right side, and plurality of rows to house power consuming devices; at least two columns of a plurality of power supply units, each of the at least two columns mounted externally to two or more of the front side, the back side, the left side and the right side of the at least one rack, each of the at least two columns of the plurality of power supply units extending along a height of the at least one rack, each of the plurality of power supply units in each of the at least two columns being arranged in a vertical orientation and vertically stacked on top of each other in the vertical orientation; and one or more connection components to connect power that is output from the plurality of power supply units of the least two columns into individual rows of the plurality of rows of the at least one rack to supply power to power consuming devices housed in rows of the at least one rack.

In some aspects, the techniques described herein relate to an apparatus, wherein the at least two columns of power supply units are arranged adjacent and parallel to each other and mounted external to the front side, the back side, the left side or the right side of the at least one rack.

In some aspects, the techniques described herein relate to an apparatus, wherein the plurality of power supply units in the at least two columns include one or more power supply unit shelves each of which includes a plurality of power supply units.

In some aspects, the techniques described herein relate to an apparatus, wherein the one or more connection components include cables or bus bars configured to distribute power output from the plurality of power supply units into the at least one rack at each of the plurality of rows of the at least one rack to provide power to the power consuming devices in the at least one rack.

In some aspects, the techniques described herein relate to an apparatus, wherein the at least two columns of power supply units includes two or more laterally stacked layers of power supply units.

In some aspects, the techniques described herein relate to a method including: mounting externally to at least one of a front side, a back side, a left side and a right side of at least one rack, at least one column of a plurality of power supply units, the at least one column of the plurality of power supply units extending along a height of the at least one rack; and connecting power output from the plurality of power supply units into individual rows of a plurality of rows of the at least one rack to supply power to power consuming devices housed in rows of the at least one rack.

In some aspects, the techniques described herein relate to a method, wherein each of the plurality of power supply units are arranged in a vertical orientation and vertically stacked on top of each other in the vertical orientation.

In some aspects, the techniques described herein relate to a method, wherein each of the plurality of power supply units are arranged in a horizontal orientation and vertically stacked on top of each other in the horizontal orientation.

In some aspects, the techniques described herein relate to a method, wherein mounting includes mounting at least two columns of power supply units arranged adjacent and parallel to each other to the front side, the back side, the left side or the right side of the at least one rack.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of’ can be represented using the ‘(s)’nomenclature (e.g., one or more element(s)).

Each example embodiment disclosed herein has been included to present one or more different features. However, all disclosed example embodiments are designed to work together as part of a single larger system or method. This disclosure explicitly envisions compound embodiments that combine multiple previously discussed features in different example embodiments into a single system or method.

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

Further, the present disclosure may repeat reference numerals and/or letters in the various examples. This repetition is for the purpose of simplicity and clarity and does not in itself dictate a relationship between the various embodiments and/or configurations discussed. Example embodiments that may be used to implement the features and functionality of this disclosure are described with more particular reference to the accompanying figures above.

Similarly, when used herein, the term “comprises” and its derivations (such as “comprising”, etc.) should not be understood in an excluding sense, that is, these terms should not be interpreted as excluding the possibility that what is described and defined may include further elements, steps, etc. Meanwhile, when used herein, the term “approximately” and terms of its family (such as “approximate”, etc.) should be understood as indicating values very near to those which accompany the aforementioned term. That is to say, a deviation within reasonable limits from an exact value should be accepted, because a skilled person in the art will understand that such a deviation from the values indicated is inevitable due to measurement inaccuracies, etc. The same applies to the terms “about” and “around” and “substantially.”

What is claimed is:

1. An apparatus comprising:
at least one rack having a front side, a back side, a left side and a right side, and plurality of rows each defining a shelf to house power consuming devices;
at least one column of a plurality of power supply units mounted externally to the front side, the back side, the left side or the right side of the at least one rack, the at least one column of the plurality of power supply units extending along a height of the at least one rack; and
one or more connection components to connect power output from the plurality of power supply units into individual rows of the plurality of rows of the at least one rack to supply power to power consuming devices housed in rows of the at least one rack.

2. The apparatus of claim 1, wherein each of the plurality of power supply units are arranged in a vertical orientation and vertically stacked on top of each other in the vertical orientation.

3. The apparatus of claim 1, wherein each of the plurality of power supply units are arranged in a horizontal orientation and vertically stacked on top of each other in the horizontal orientation.

4. The apparatus of claim 1, wherein the plurality of power supply units in the at least one column comprise one or more power supply unit shelves each of which comprises a plurality of power supply units.

5. The apparatus of claim 1, and comprising at least two columns of power supply units arranged adjacent and parallel to each other and mounted external to the front side, the back side, the left side or the right side of the at least one rack.

6. The apparatus of claim 1, wherein the one or more connection components comprise cables or bus bars configured to distribute power output from the plurality of power supply units into the at least one rack at each of the plurality of rows of the at least one rack to provide power to the power consuming devices in the at least one rack.

7. The apparatus of claim 1, wherein the at least one column comprises two or more laterally stacked layers of power supply units, wherein each of the plurality of power supply units in each of the two or more laterally stacked layers of power supply units are arranged in a vertical orientation and vertically stacked on top of each other in the vertical orientation.

8. The apparatus of claim 1, further comprising a housing for the at least one column of the plurality of power supply units, wherein the housing includes vertical spaces for air plenums to enable air flow across the plurality of power supply units.

9. The apparatus of claim 8, wherein the housing further includes vertical spaces for cables.

10. The apparatus of claim 9, further comprising a plurality fan modules, each fan module arranged at one of a plurality of positions in the at least one column of power supply units.

11. The apparatus of claim 1, comprising first rack and a second rack positioned adjacent to each other such that a right side of the first rack abuts a left side of the second rack, each of the first rack and the second rack having a plurality of rows each defining a shelf to house power consuming devices, a first pair of columns of power supply units arranged adjacent and parallel to each other and mounted external to a left side of the first rack, and a second pair of columns of power supply units arranged adjacent and parallel to each other and mounted external to a right side of the second rack.

12. The apparatus of claim 11, wherein each column of the first pair of columns and each column of the second pair of columns comprises two or more laterally stacked layers of power supply units, wherein each of the plurality of power supply units in each of the two or more laterally stacked layers of power supply units are arranged in a vertical orientation and vertically stacked on top of each other in the vertical orientation.

13. The apparatus of claim 1, further comprising a controller in communication with the plurality of power supply units via a current share bus to receive measurements made by each of the plurality of power supply units, the measurements indicating percentage of output current provided by each of the plurality of power supply units, and wherein the controller is configured to evaluate the measurements to select one or more of the plurality of power supply units to shut down in order to maintain operation of the plurality of power supply units at a desired power efficiency.

14. An apparatus comprising:
at least one rack having a front side, a back side, a left side and a right side, and plurality of rows to house power consuming devices;
at least two columns of a plurality of power supply units, each of the at least two columns mounted externally to two or more of the front side, the back side, the left side and the right side of the at least one rack, each of the at least two columns of the plurality of power supply units extending along a height of the at least one rack, each of the plurality of power supply units in each of the at least two columns being arranged in a vertical orientation and vertically stacked on top of each other in the vertical orientation; and
one or more connection components to connect power that is output from the plurality of power supply units of the least two columns into individual rows of the plurality of rows of the at least one rack to supply power to power consuming devices housed in rows of the at least one rack.

15. The apparatus of claim 14, wherein the at least two columns of power supply units are arranged adjacent and parallel to each other and mounted external to the front side, the back side, the left side or the right side of the at least one rack.

16. The apparatus of claim 14, wherein the plurality of power supply units in the at least two columns comprise one or more power supply unit shelves each of which comprises a plurality of power supply units.

17. The apparatus of claim 14, wherein the one or more connection components comprise cables or bus bars configured to distribute power output from the plurality of power supply units into the at least one rack at each of the plurality of rows of the at least one rack to provide power to the power consuming devices in the at least one rack.

18. The apparatus of claim 14, wherein the at least two columns of power supply units comprises two or more laterally stacked layers of power supply units.

19. A method comprising:
mounting externally to at least one of a front side, a back side, a left side and a right side of at least one rack, at least one column of a plurality of power supply units, the at least one column of the plurality of power supply units extending along a height of the at least one rack; and
connecting power output from the plurality of power supply units into individual rows of a plurality of rows of the at least one rack to supply power to power consuming devices housed in rows of the at least one rack.

20. The method of claim 19, wherein each of the plurality of power supply units are arranged in a vertical orientation and vertically stacked on top of each other in the vertical orientation.

21. The method of claim 19, wherein each of the plurality of power supply units are arranged in a horizontal orientation and vertically stacked on top of each other in the horizontal orientation.

22. The method of claim 19, wherein mounting comprises mounting at least two columns of power supply units arranged adjacent and parallel to each other to the front side, the back side, the left side or the right side of the at least one rack.
